(19) United States
(12) Patent Application Publication
(10) Pub. No.: US 2015/0334889 A1
(43) Pub. Date: Nov. 19, 2015

(54) ELECTRONIC-COMPONENT MOUNTING SYSTEM

(71) Applicant: Panasonic Intellectual Property Management Co.,Ltd., Osaka (JP)

(72) Inventors: Ryota NISHIJIMA, Yamanashi (JP); Kenji OKAMOTO, Hyogo (JP); Kunio YAMAMOTO, Yamanashi (JP); Hisashi MAEZONO, Yamanashi (JP)

(21) Appl. No.: 14/651,518

(22) PCT Filed: Dec. 6, 2013
(86) PCT No.: PCT/JP2013/007208

§ 371 Date: Jun. 11, 2015

(30) Foreign Application Priority Data
Dec. 12, 2012 (JP) 2012-271044

(51) Int. Cl. H05K 13/08

(52) U.S. Cl. CPC H05K 13/08

(57) ABSTRACT

An electronic-component mounting system includes: mounting lines each including an electronic-component mounting apparatus; an operation information processor which collects operation information of the electronic-component mounting apparatus, applies a statistical process on the operation information, and produces operation quality information of the mounting lines; and a portable information terminal accessible to the operation information processor by wireless communication. An identification information transmission section which transmits identification information for identifying each of the mounting lines is disposed in each mounting line, and a reception section which receives the identification information is disposed in the portable information terminal. The portable information terminal displays on a display section thereof the operation quality information of one of the mounting lines located near the portable information terminal based on the identification information transmitted from the mounting lines.

### TECHNICAL FIELD

The present invention relates to an electronic-component mounting system for mounting electronic components on a circuit board.

### BACKGROUND ART

In the field of electronic component mounting, a mounting line includes a plurality of component mount apparatuses for producing a mounted board in which electronic components are mounted on a circuit board is usually used. Such component mount apparatuses include an electronic-component mounting apparatus which picks up an electronic component from a component supply section by a mounting head, and which mounts the electronic component on a circuit board that is transported to a predetermined position.

In a mounting line, an information collection section is disposed. The information collection section collects information (operation information) relating to a component mounting work and sequentially transmitted from an electronic-component mounting apparatus through a communication network, and statistically processes the information. The information collection section includes a monitor which functions as a display section, and displays information (operation quality information) obtained by statistically processing the operation information, on the monitor. By viewing the information displayed on the monitor, the worker can check the operation quality information of the mounting line or the electronic-component mounting apparatus through numeric data or the like.

### RELATED ART DOCUMENTS

### Patent Documents

Patent Document 1: JP-A-2001-142519

### SUMMARY OF THE INVENTION

### Problem to be Solved by the Invention

In a large-scale production factory, a plurality of mounting lines are provided, and information collection sections are often disposed fixedly in a monitoring room or the like which is separated from the mounting lines. Therefore, in order to check the operation quality information of a specific mounting line or electronic-component mounting apparatus, the worker bothers to move to the place where the information collection section for a mounting line to be checked is disposed, and the checking work requires a prolonged period of time. Further, in the case where a certain failure occurs and the operation of an electronic-component mounting apparatus is stopped, the worker must move to the information collection section to check the operation quality information, in order to search the cause of the failure. Therefore, a prolonged period of time is necessary to search the cause of the failure.

Usually, a plurality of electronic-component mounting apparatuses are disposed in one mounting line. In this case, the operation quality information can be checked for each of electronic-component mounting apparatuses through a monitor of an information collection section, but there is a problem in that, when the worker erroneously operates the information collection section, the operation quality information of another electronic-component mounting apparatus is displayed on the monitor.

An object of the present invention is to provide an electronic-component mounting system including a mounting line including an electronic-component mounting apparatus in which the worker can easily check the operation quality information through the portable information terminal, near the mounting line or the electronic-component mounting apparatus

### Means for Solving the Problem

The present invention provides an electronic-component mounting system including: a plurality of mounting lines, each of which includes an electronic-component mounting apparatus which performs a work of mounting an electronic component on a circuit board; operation information processing means for collecting operation information of the electronic-component mounting apparatus, applying a statistical process on the operation information, and producing operation quality information of the mounting lines; and at least one portable information terminal which includes a main section and a display section, and which is accessible to the operation information processing means by wireless communication, wherein an identification information transmission section which transmits identification information for identifying each of the mounting lines is disposed in each of the plurality of mounting lines, and a reception section which receives the identification information is disposed in the main section of the portable information terminal, and wherein the portable information terminal has a function of displaying on the display section the operation quality information of one of the mounting lines which is located near the portable information terminal based on the identification information transmitted from the mounting lines.

Further, the present invention provides an electronic-component mounting system including: a mounting line including a plurality of electronic-component mounting apparatuses, each of which performs a work of mounting an electronic component on a circuit board; operation information processing means for collecting operation information of the electronic-component mounting apparatuses, applying a statistical process on the operation information, and producing operation quality information of the electronic-component mounting apparatuses; and at least one portable information terminal which includes a main section and a display section, and which is accessible to the operation information processing means by wireless communication, wherein an identification information transmission section which transmits identification information for identifying each of the electronic-component mounting apparatus is disposed in each of the plurality of electronic-component mounting apparatuses, and a reception section which receives the identification information is disposed in the main section of the portable information terminal, and wherein the portable information terminal has a function of displaying on the display section the operation quality information of one of the electronic-component mounting apparatuses which is located near the portable information terminal based on the identification information transmitted from the electronic-component mounting apparatuses.

### Advantages of the Invention

According to the invention, the system includes at least one portable information terminal which is accessible to the operation information processing means by wireless communication for producing the operation quality information, and therefore the worker can easily check the operation quality information through the portable information terminal, near the mounting line or the electronic-component mounting apparatus.

Moreover, according to the invention, the portable information terminal the function of displaying on the display section the operation quality information of the mounting line which is located in the vicinity of the portable information terminal based on identification information transmitted from the mounting lines. Therefore, when the worker approaches a mounting line, the worker can check the operation quality information of the mounting line, quickly and easily.

Furthermore, according to the invention, the portable information terminal is provided with the function of displaying on the display section the operation quality information of the electronic-component mounting apparatus which is located in the vicinity of the portable information terminal based on identification information transmitted from the electronic-component mounting apparatuses. Therefore, when the worker approaches an electronic-component mounting apparatus, the worker can check the operation quality information of the electronic-component mounting apparatus, quickly and easily.

### BRIEF DESCRIPTION OF THE DRAWINGS

FIG. 1 is a diagram of a whole electronic-component mounting system of an embodiment of the invention.

FIG. 2 is a plan view of a portable information terminal in the embodiment.

FIG. 3 is a diagram showing the configuration of a controlling system in the embodiment.

FIG. 4 is a diagram showing a manner of communication between electronic-component mounting apparatuses and portable information terminal in the embodiment.

FIG. 5 is a view showing information displayed on a display section of the portable information terminal in the embodiment.

FIG. 6 is a view showing information displayed on the display section of the portable information terminal in the embodiment.

FIG. 7 is a view showing information displayed on the display section of the portable information terminal in the embodiment.

FIG. 8 is a view showing information displayed on the display section of the portable information terminal in the embodiment.

FIG. 9 is a view showing information displayed on the display section of the portable information terminal in the embodiment.

FIG. 10 is a flowchart showing an operation of a display target automatic selection process in the embodiment.

### MODE FOR CARRYING OUT THE INVENTION

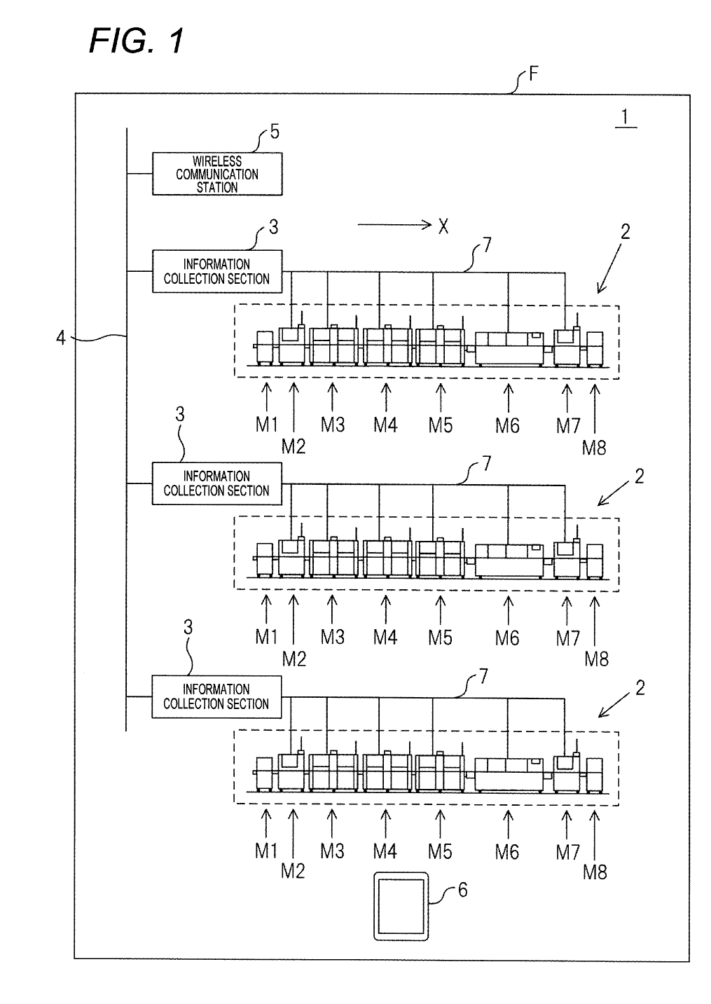

An embodiment of the invention will be described with reference to the drawings. Referring to FIG. 1, an electronic-component mounting system 1 has a function of mounting electronic components on a circuit board to produce a mounted board, and includes: a plurality (in the embodiment, three) of mounting lines 2; information collection sections 3 which are disposed in the mounting lines 2, respectively; a wireless communication station 5 which is connected to the information collection sections 3 through an intranet 4; and an portable information terminal 6. The electronic-component mounting system 1 is provided on one factory floor F.

Each of the mounting lines 2 includes a plurality of component mount apparatuses which perform various works for mounting electronic components on a circuit board, and is formed by series connecting a board supplying apparatus M1, a solder printing apparatus M2, electronic-component mounting apparatuses M3, M4, M5, a reflow apparatus M6, an inspection apparatus M7, and a board recovering apparatus M8, with starting from the upstream side (the left side of the sheet of FIG. 1) in the board transporting direction (X direction). The apparatuses ranging from the board supplying apparatus M1 to the board recovering apparatus M8 are connected to the information collection section 3 through a communication network 7. Hereinafter, an electronic-component mounting apparatus is referred to simply as “mounting machine”.

The board supplying apparatus M1 is placed in the forefront of the mounting line 2, and supplies a circuit board which is a target of mounting of electronic components, to the solder printing apparatus M2. The solder printing apparatus M2 screen prints solder for component bonding, onto electrodes formed on the upper surface of the circuit board. The mounting machines M3 to M5 mount electronic components on the circuit board on which the screen printing has been performed. The reflow apparatus M6 heats the circuit board on which electronic components have been mounted, in accordance with a predetermined heating profile, thereby causing the solder to melt and solidify. The inspection apparatus M7 checks the mounted state such as positional displacements of the solder-bonded electronic components with respect to the electrodes. The board recovering apparatus M8 recovers the mounted board which has undergone the checking process.

In the embodiment, a circuit board which has undergone the component mounting operations in the mounting machines M3 to M5 is referred to as “component-mounted board”. A circuit board which has undergone the component mounting operations in the mounting machines M3 to M5, and the heating process in the reflow apparatus M6 is referred to as “mounted board”. Moreover, the various works in the solder printing apparatus M2, the mounting machines M3 to M5, and the reflow apparatus M6 are generally referred to as “mounting work”.

Next, Each of the mounting machines M3 to M5 includes: a board transporting mechanism for transporting a circuit board to position the board at a predetermined work position; a feeder (tape feeder) which pitch-feeds a carrier tape accommodating electronic components to supply the electronic components to a component pick-up position; a mounting head which includes a suction nozzle that can suck an electronic component, and which is horizontally movable; and a recognition camera in which the imaging direction is upward directed (all the members are not shown). These mechanisms and members are operated by respective control sections disposed in the mounting machines M3 to M5.

Next, the component mounting operation in each of the mounting machines M3 to M5 will be described. The control section causes the suction nozzle to suck from the upper side an electronic component which is supplied to the component pick-up position by the feeder. Next, the control section causes the mounting head to move to a position above the circuit board through the space above the recognition camera while maintaining the sucked state. At this time, the control section causes the recognition camera to take an image of the suction nozzle which passes above the recognition camera, and performs a recognition process to calculate the positional displacement amount of the electronic component with respect to the suction nozzle. Then, the control section corrects the lowered position and attachment angle of the suction nozzle based on the positional displacement amount, and thereafter causes the suction nozzle to be lowered, and the electronic component to be mounted on the circuit board which is located to the predetermined work position.

As described above, the plurality of mounting lines 2 include the mounting machines M3 to M5 which perform the work of mounting electronic components on a circuit board. Moreover, each mounting line 2 includes the plurality of the mounting machines M3 to M5. The above-described configuration and operation of the mounting machines M3 to M5 are known.

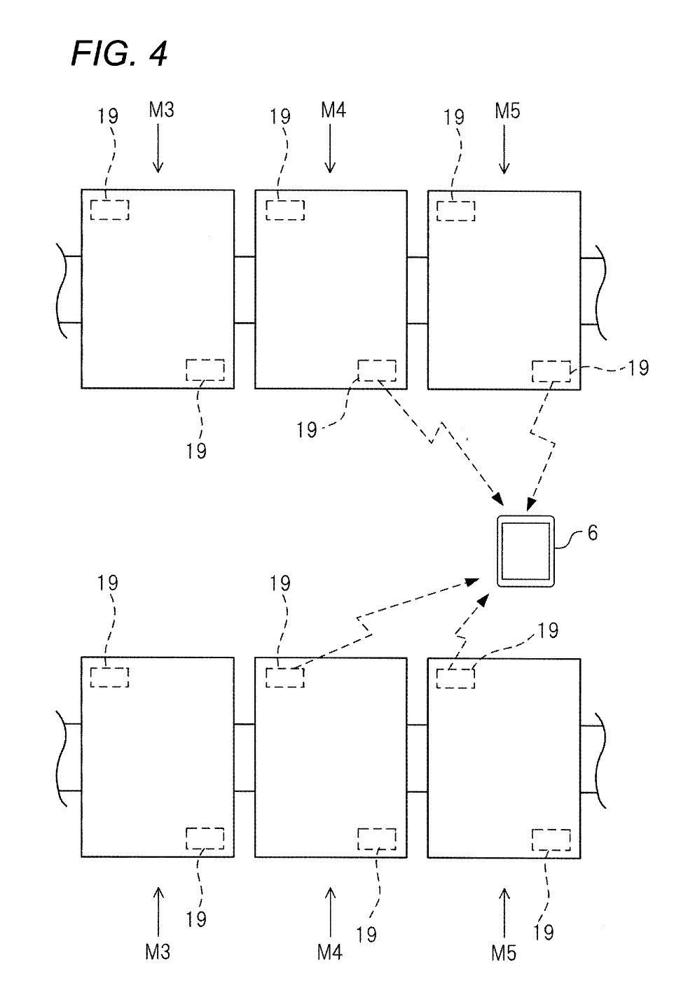

Referring to FIG. 4, the mounting machine M3 to M5 includes a wireless communication section 19 which transmits a radio wave containing unique identification information for identifying the mounting machine M3 to M5. The wireless communication section 19 transmits the radio wave even during a suspension of the mounting machine M3 to M5. A process section 14 of the portable information terminal 6 which will be described later specifies one of the mounting machines M3 to M5 or one of the mounting lines 2 to which the mounting machines M3 to M5 belongs, based on the identification information. As described above, the wireless communication sections 19 function as an identification information transmission section which transmits the identification information for identifying the mounting machines M3 to M5 (mounting lines 2).

Referring to FIG. 1, each of the information collection sections 3 collects and statistically processes operation information which is sequentially transmitted through the communication network 7 from the control sections of the component mount apparatuses including the mounting machines M3 to M5, and includes a monitor which is not shown. The information collection section 3 includes a storage region which collects (stores) operation information, and statistically processes the operation information which is collected in the storage region.

The operation information means various kinds of information related to the mounting work, such as: the number of component-mounted boards which are produced by the mounting machines M3 to M5; that of mounted boards which are produced by the mounting line 2; the kinds and number of electronic components mounted on circuit boards; the number of failures in the mounting work; and various periods of time (operation time, board transportation waiting time, board discharge waiting time, and non-operating time which will be described later) which occur after the start of production in the mounting line 2.

The information collection section 3 newly produces various kinds of information (data) including the operation quality information of the mounting line 2 and the mounting machines M3 to M5, based on the operation information, and the produced information is stored in the storage region. The various kinds of information produced by the information collection section 3 are sequentially updated based on the operation information transmitted from the component mount apparatuses, and displayed on the monitor of the information collection section 3.

The operation quality information is information which is produced by statistically processing the operation information by the information collection section 3 (the detail will be described later). As described above, the information collection section 3 functions as operation information processing means for collecting and statistically processing the operation information of the mounting machines M3 to M5, and producing the operation quality information of the mounting line 2 (electronic-component mounting machines M3 to M5).

Referring to FIG. 1, the wireless communication station 5 is a radio repeater which connects the information collection sections 3 and the portable information terminal 6 in a mutually communicable manner by means of a wireless LAN (Local Area Network). The wireless communication station 5 transmits a radio signal which uses a radio wave as a medium. When the portable information terminal 6 receives the radio signal, various data communications are enabled between the information collection sections 3 and the portable information terminal 6 through the wireless communication station 5.

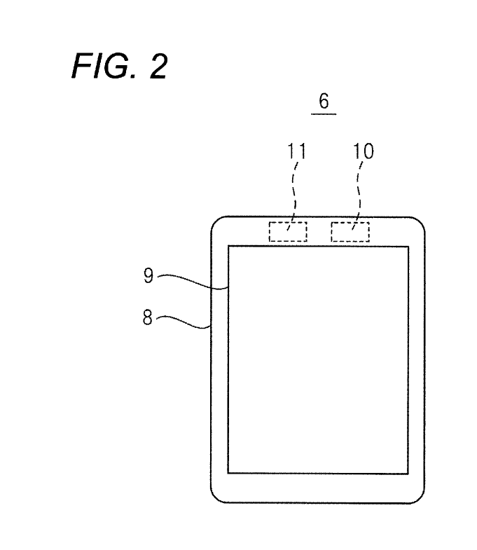

Next, the portable information terminal 6 will be described with reference to FIG. 2. The portable information terminal 6 has functions of performing wireless communication with the wireless communication station 5 or the mounting machines M3 to M5, and displaying various kinds of information stored in the information collection sections 3. The portable information terminal 6 has a weight and size which enable the worker to hold and carry the terminal with the hand, and includes the main section 8 and a touch panel 9. At least one portable information terminal 6 may be disposed in one electronic-component mounting system 1.

The main section 8 includes a first wireless communication section 10 and a second wireless communication section 11. The first wireless communication section 10 receives the radio signal transmitted from the wireless communication station 5, and transmits and receives various data to and from the information collection sections 3. A communication system as used herein preferably allows a long-distance communication between the information collection sections 3 and the portable information terminal 6.

The second wireless communication section 11 has a function of a reception section which receives the identification information transmitted from the wireless communication sections 19 of the mounting machines M3 to M5 (see FIG. 4). A communication system as used herein preferably allows communication at a distance shorter than the above-described communication distance between the wireless communication station 5 and the first wireless communication section 10.

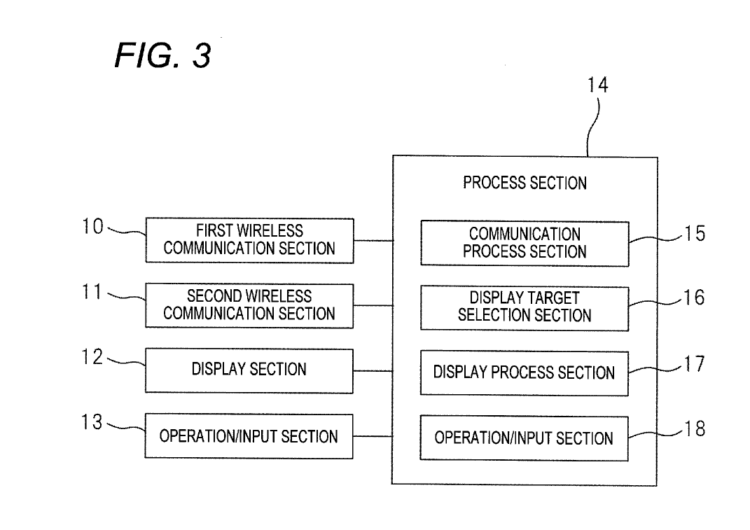

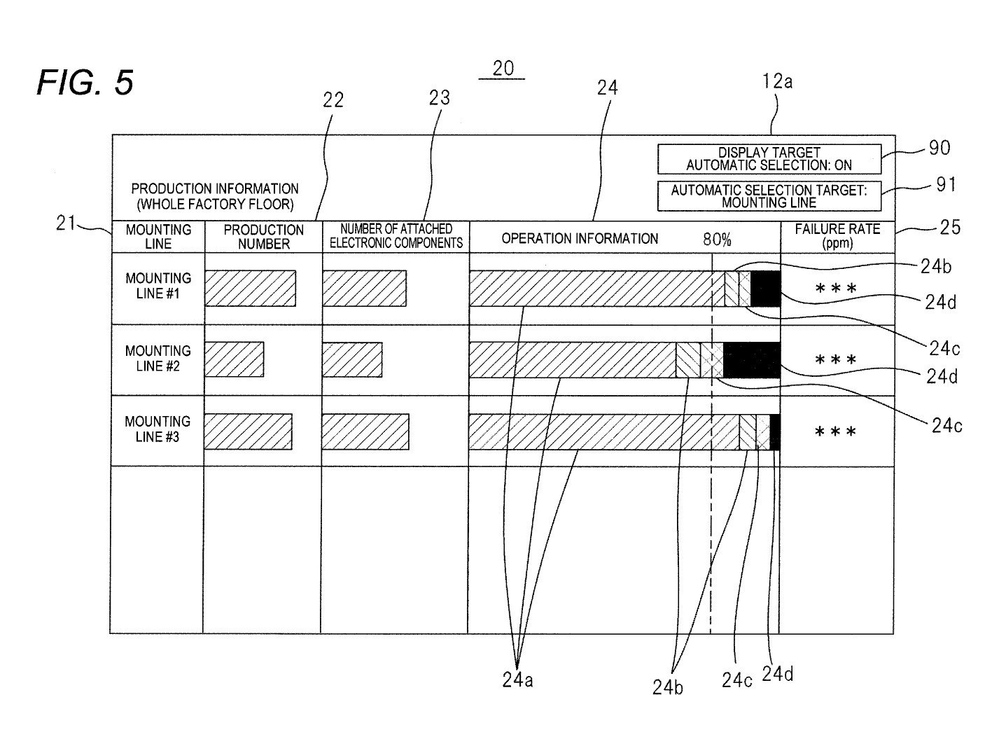

The touch panel 9 is a combination of a display section 12 and an operation/input section 13 (see FIG. 3). The display section 12 includes a display screen 12a (see FIGS. 5 to 9) formed by a liquid crystal panel for displaying various kinds of information, and the like. When the worker operates an arbitrary display on the display screen 12a, it is possible to intuitively perform an operation such as switching of the display screen and various inputs. Here, the operation means an operation (so-called tapping) of slightly tapping on the display screen 12a with the finger, a dedicated touch pen, or the like. When a scrolling operation is performed vertically or horizontally in a state where the finger or a touch pen is contacted at an arbitrary position of the display screen 12a, information which is in hiding outside the display screen 12a can be displayed.

Next, the configuration of the controlling system of the portable information terminal 6 will be described with reference to FIG. 3. The process section 14 of the portable information terminal 6 includes a communication process section 15, a display target selection section 16, a display process section 17, and an operation/input section 18. The process section 14 is connected to the first wireless communication section 10, the second wireless communication section 11, the display section 12, and the operation/input section 13.

The communication process section 15 accesses the information collection sections 3 through the wireless communication station 5 and the first wireless communication section 10, and performs a communication process on various data. The display target selection section 16 performs a process of specifying the mounting machine M3 to M5 which is the display target, or the mounting line 2 to which the mounting machine M3 to M5 belongs, based on the identification information received by the second wireless communication section 11. The above-described process to be performed by the display target selection section 16 is performed in the case where the display target automatic selection is valid (the detail will be described later).

The display process section 17 performs a process of displaying information of the display target which is specified by the display target selection section 16, and various switches, on the display screen 12a, and also that of switching the display screen 12a so as to display various kinds of information selected on the display screen 12a by the worker. The operation/input section 18 performs processes of operations, various inputs, and the like through the touch panel 9. As described above, the portable information terminal 6 includes the main section 8 and the display section 12, and can access the operation information processing means through wireless communication.

Next, various kinds of information which are to be displayed on the display section 12 will be described with reference to FIGS. 5 to 9. On the display section 12 (display screen 12a), various kinds of information in the mounting lines 2 and the mounting machines M3 to M5 are individually displayed. Specifically, information including “Factory floor data 20”, “Unit mounting line data 30”, “Unit mounting machine data 50”, “Component information data 70”, and “Next-production data 80” is displayed on the display screen 12a. Also, “Display target automatic selection switch 90” and “Automatic-selection target selection switch 91” are additionally displayed on the display screen 12a on which the data are displayed. The data are produced by the information collection sections 3 based on the operation information.

First, the factory floor data 20 will be described with reference to FIG. 5. In the factory floor data 20, various kinds of production information in the all mounting lines 2 provided on the factory floor F are shown for each of the mounting lines 2. Specifically, the factory floor data 20 include various kinds of information of “Mounting line” 21, “Production number” 22, “Number of attached electronic components” 23, “Operation information” 24, and “Failure rate (ppm) 25”. One row corresponds to one mounting line 2.

“Mounting line” 21 indicates information for specifying each mounting line 2 (for example, the name, identification number, or the like of the mounting line). “Production number” 22 indicates the total production number of mounted boards in each mounting line 2 in the form of a bar graph. “Number of attached electronic components” 23 indicates the total number of electronic components which are mounted on circuit boards in the mounting machines M3 to M5 belonging to each mounting line 2, for the mounting line 2 in the form of a bar graph. “Operation information” 24 indicates ratios of various periods of times which occur after the start of production in each mounting line 2, in the form of a bar graph. “Failure rate (ppm)” 25 indicates the occurrence rate of failures in the mounting work, for each mounting line 2.

“Operation information” 24 will be described in detail. In “Operation information” 24, ratios of: “Operation time” 24a indicating a period of time when a substantial mounting work for producing mounted boards is performed in each mounting line 2; “Board transportation waiting time” 24b indicating a period of time when, because the mounting work in a component mount apparatus on the upstream side is delayed for any reason, waiting for transportation of a circuit board occurs in a component mount apparatus on the downstream side; “Board discharge waiting time” 24c indicating a period of time when, because the mounting work in a component mount apparatus on the downstream side is delayed for any reason, waiting for discharge of a circuit board occurs in a component mount apparatus on the upstream side; and “Non-operating time” 24d indicating a period of time when the operation of the mounting line 2 is stopped for a reason such as a failure in the mounting work or component shortage are shown in the form of a bar graph.

An indication of “80%” is displayed at the point of 80% of the whole bar graph. The determination whether the mounting line 2 maintains a constant operation state or not is made by determining whether the bar graph indicating “Operation time” 24a exceeds the display of 80% or not.

In the factory floor data 20, information which is obtained by combining “Operation information” 24 and “Failure rate (ppm)” 25 is operation quality information for each mounting line 2. Namely, the operation quality information displayed in the factory floor data 20 includes information relating to various periods of time after the start of the production in each mounting line 2, and that relating to a failure in the mounting work occurring in the mounting line 2. The information relating to a failure in the mounting work includes the occurrence rate of failures in the mounting work in the mounting line 2.

When viewing the operation quality information displayed on the display screen 12a, the worker can check various operation states in each mounting line 2. In the case where the ratio (operation ratio) of “Operation time” 24a is lowered, the cause can be analyzed by checking the ratios of the other periods of time, and measures for correction such as changing of settings of operation parameters in the mounting machines M3 to M5 can be quickly taken.

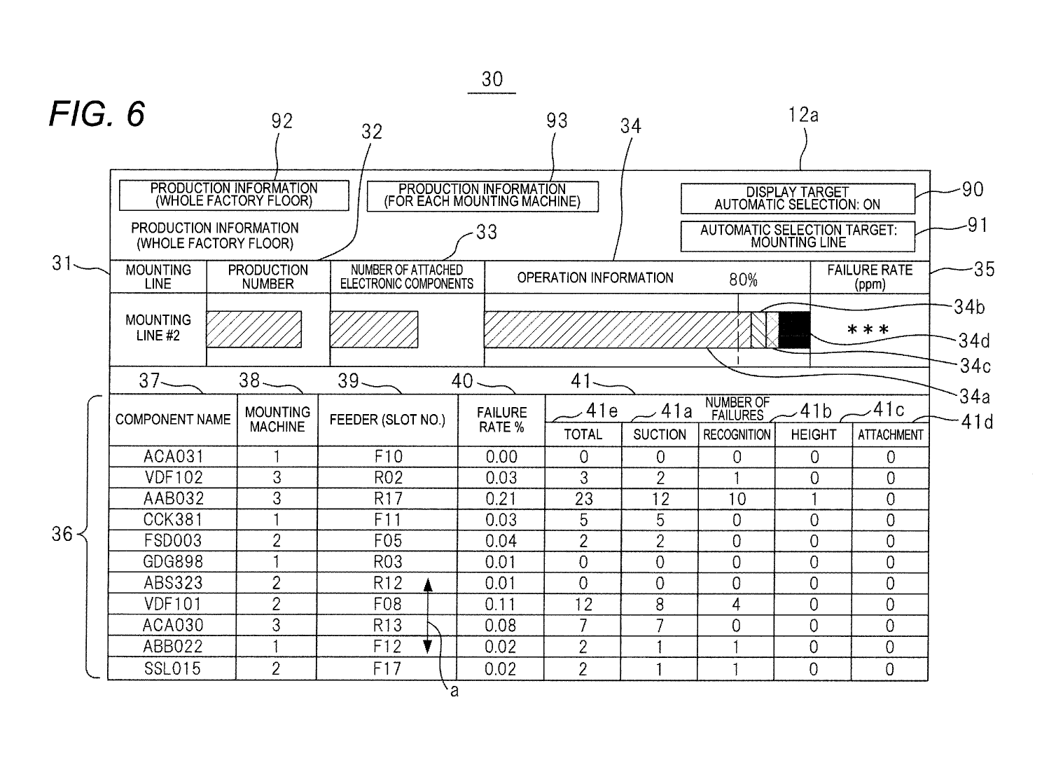

Next, the unit mounting line data 30 will be described with reference to FIG. 6. The unit mounting line data 30 indicate various kinds of production information in each mounting line 2. Specifically, the unit mounting line data 30 include various kinds of information of “Mounting line” 31 indicating the mounting line 2 which is the display target, “Production number” 32, “Number of attached electronic components” 33, “Operation information” 34, “Failure rate (ppm)” 35, and “Component information” 36.

In the information, the contents of “Mounting line” 31, “Production number” 32, “Number of attached electronic components” 33, “Operation information” 34, and “Failure rate (ppm)” 35 are similar to “Mounting line” 21, “Production number” 22, “Number of attached electronic components” 23, “Operation information” 24, “Failure rate (ppm)” 25 which have been described with respect to the factory floor data 20. Also the contents of “Operation time” 34a, “Board transportation waiting time” 34b, “Board discharge waiting time” 34c, and “Non-operating time” 34d constituting “Operation information” 34 are similar to “Operation time” 24a, “Board transportation waiting time” 24b, “Board discharge waiting time” 24c, and “Non-operating time” 24d which have been described with respect to the factory floor data 20.

“Component information” 36 indicates information relating to electronic components which are targets of the mounting work in each mounting line 2 that is the display target, and includes various kinds of information of “Component name” 37, “Mounting machine” 38, “Feeder (Slot No.)” 39, “Failure rate %” 40, and “Number of failures” 41. One row corresponds to one component name. When the arbitrary position in “Component information” 36 is scrolled vertically (the arrow a), “Component information” 36 which is in hiding outside the display screen 12a can be displayed.

“Component name” 37 indicates the names of electronic components which are targets of the mounting work in each mounting line 2 that is the display target. “Mounting machine” 38 indicates the identification numbers of the mounting machines M3 to M5 which perform the operation of mounting respective electronic components. “Feeder (Slot No.)” 39 indicates information (the ID, slot number, or the like allocated to a feeder) for specifying the feeder which supplies an electronic component, or the location of the feeder. “Failure rate %” 40 indicates the occurrence rate of mounting failures in the mounting machines M3 to M5, for each electronic component. “Number of failures” 41 indicates specific contents of a mounting failure for each electronic component, together with the number of occurrences.

“Number of failures” 41 will be described in detail. “Number of failures” 41 includes information of: “Suction” 41a indicating the number of failures of the operation of sucking an electronic component by the suction nozzle; “Recognition” 41b indicating the number of failures of recognition of an electronic component by the recognition camera; “Height” 41c indicating the number of detections of an abnormal attitude of an electronic component sucked by the suction nozzle; “Attachment” 41d indicating the number of situations in which an electronic component cannot be mounted on a circuit board because, for example, the electronic component fails to be detached from the suction nozzle; and “Total” 41e which is a total of the occurrence numbers of “Suction” 41a to “Attachment” 41d. “Total” 41e means the number of mounting failures.

In the unit mounting line data 30, “Operation information” 34, “Failure rate (ppm)” 35, and “Component information” 36 function as the operation quality information in the mounting line 2. Namely, the operation quality information which is displayed in the unit mounting line data 30 includes information relating to various periods of time after the start of production in the mounting line 2, and that relating to failures in the mounting work in the mounting line 2. The information relating to failures in the mounting work includes the occurrence rate of failures in the mounting work in the mounting line 2, and the number and rate of mounting failures for each electronic component in the mounting machines M3 to M5. In the case where the operation ratio is lowered, when the worker checks the information of “Failure rate %” 40, “Number of failures” 41, and the like of “Component information” 36, analysis of the cause, and corrective action can be performed in the vicinity of the mounting line 2.

When the worker operates an arbitrary component name in “Component name” 37, the process section 14 switches the display screen 12a so as to display the component information data 70 corresponding to the component name. When the worker operates an arbitrary identification number in “Mounting machine” 38, the process section 14 switches the display screen 12a so as to display the unit mounting machine data 50 of the mounting machine M3 to M5 corresponding to the identification number.

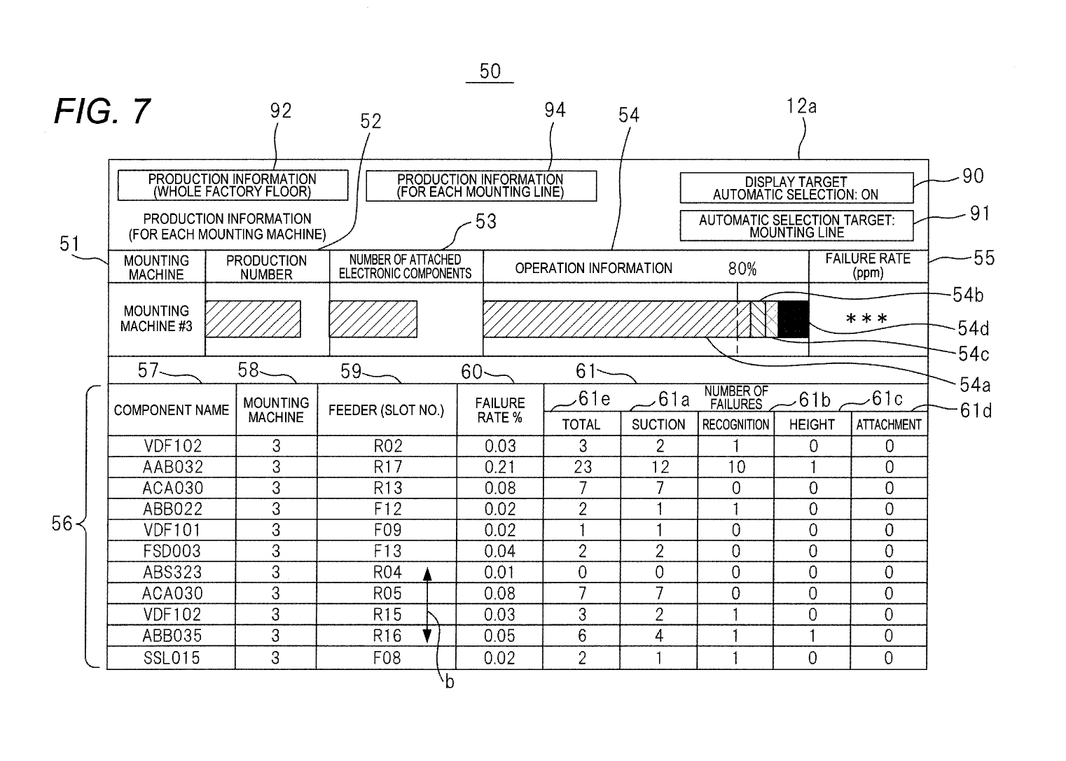

Next, the unit mounting machine data 50 will be described with reference to FIG. 7. The unit mounting machine data 50 indicate various kinds of production information for each of the mounting machines M3 to M5. Specifically, the unit mounting machine data 50 include various kinds of information of “Mounting machine” 51, “Production number” 52, “Number of attached electronic components” 53, “Operation information” 54, “Failure rate (ppm)” 55, and “Component information” 56.

“Mounting machine” 51 indicates information for identifying each mounting machine (for example, the name or identification number of the mounting apparatus). “Production number” 52 indicates the total production number of component-mounted boards in each mounting machine which is the display target, in the form of a bar graph. “Number of attached electronic components” 53 indicates the total number of electronic components which are mounted on circuit boards in the mounting machine which is the display target, in the form of a bar graph.

“Operation information” 54 indicates various periods of times which occur after the start of production in the mounting machine which is the display target, i.e., ratios of “Operation time” 54a, “Board transportation waiting time” 54b, “Board discharge waiting time” 54c, and “Non-operating time” 24d, in the form of a bar graph. “Failure rate (ppm)” 55 indicates the occurrence rate of failures in the mounting work, in the mounting machine which is the display target. The contents of the various periods of times in “Operation information” 54 are similar to the various periods of times of “Operation information” 24, 34 which have been described with respect to the factory floor data 20 and the unit mounting line data 30.

“Component information” 56 indicates information relating to electronic components which are targets of the mounting work in the mounting machine that is the display target, and includes various kinds of information of “Component name” 57, “Mounting machine” 58, “Feeder (Slot No.)” 59, “Failure rate %” 60, and “Number of failures” 61. One row corresponds to one component name. When the arbitrary position in “Component information” 56 is scrolled vertically (the arrow b), “Component information” 56 which is in hiding outside the display screen 12a can be displayed.

“Component name” 57 indicates the names of electronic components on which the mounting work is performed in the mounting machine that is the display target. “Mounting machine” 58 indicates information (the name, the identification number, or the like) for specifying the mounting machine which performs the operation of mounting each electronic component. The unit mounting machine data 50 indicates information for each mounting machine, and therefore all sets of information indicated in “Mounting machine” 58 are identical.

“Feeder (Slot No.)” 59 indicates information (the ID, slot number, or the like allocated to a feeder) for specifying the feeder which supplies an electronic component in the mounting machine that is the display target, or the location of the feeder. “Failure rate %” 60 indicates the occurrence rate of mounting failures with respect to each electronic component in the mounting machine that is the display target. “Number of failures” 61 indicates the specific cause of a mounting failure for each electronic component in the mounting machine that is the display target, together with the number of occurrences, and includes information of “Suction” 61a, “Recognition” 61b, “Height” 61c, “Attachment” 61d, and “Total” 61e. The contents of the information are similar to information included in “Number of failures” 41 which has been described with respect to the unit mounting line data 30.

In the unit mounting machine data 50, “Operation information” 54, “Failure rate (ppm)” 55, and “Component information” 56 function as operation quality information for each of the mounting machines M3 to M5. Namely, the operation quality information displayed in the unit mounting machine data 50 includes information relating to various periods of time after the start of the production in the mounting machine M3 to M5, and that relating to a failure in the mounting work occurring in the mounting machine M3 to M5. The information relating to failures in the mounting work includes the occurrence rate of failures in the mounting work, and the number and rate of mounting failures for each electronic component in the mounting machine M3 to M5. When the worker operates an arbitrary component name in “Component name” 57, the process section 14 switches the display screen 12a so as to display the component information data 70 corresponding to the component name.

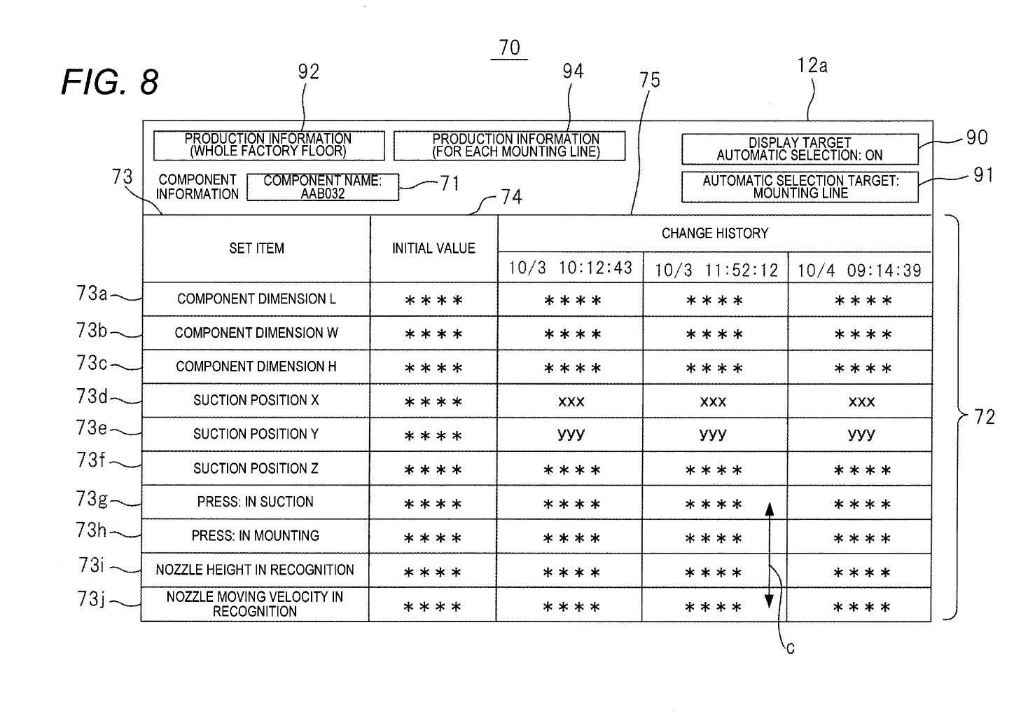

Next, the component information data 70 will be described with reference to FIG. 8. The component information data 70 indicate operation parameters which are necessary in the operations of mounting components in the mounting machine M3 to M5, for each component name. With using the operation parameters, the control section disposed in the mounting machine M3 to M5 performs the processes of operating the suction nozzle and recognition by using the recognition camera. The component information data 70 include information of “Component name” 71 and “Detailed component information” 72, and “Detailed component information” 72 includes information of “Set item” 73, “Initial value” 74, and “Change history” 75. When the arbitrary position in “Detailed component information” 72 is scrolled vertically (the arrow c), “Detailed component information” 72 which is in hiding outside the display screen 12a can be displayed.

“Component name” 71 indicates the names of electronic components which are display targets. “Set item” 73 includes items of: “Component dimension L” 73a, “Component dimension W” 73b, and “Component dimension H” 73c indicating the longitudinal, width, and vertical dimensions of an electronic component; “Suction position X” 73d, “Suction position Y” 73e, and “Suction position Z” 73f indicating the positions in the horizontal direction (the X direction and the Y direction (perpendicular to the X direction)) and position in the vertical direction (the Z direction) of the suction nozzle in the case where an electronic component is to be sucked from the upper side; “Press: in suction” 73g indicating the pressing amount (pressing force) which is applied to an electronic component by the suction nozzle in the case where the electronic component is sucked by the suction nozzle; “Press: in mounting” 73h indicating the pressing amount which is applied to the circuit board by the suction nozzle in the case where the suction nozzle is lowered and the electronic component is mounted on the circuit board; “Nozzle height in recognition” 73i indicating the height of the suction nozzle in the case where the electronic component is recognized (imaged) by the recognition camera; “Nozzle moving velocity in recognition” 73j indicating the moving velocity of the suction nozzle in recognition (imaging) of the electronic component by the recognition camera; etc.

“Initial value” 74 indicates initial set values of the set items 73a to 73j. “Change history” 75 indicates the value at a timing when the worker changes the set values of the set items 73a to 73j, for each date and time when the changing work is performed. The set values of the set items 73a to 73j are suitably changed by the worker based on the occurrence rate of the mounting failure and its specific cause which are displayed in “Component information” 36, 56 in the unit mounting line data 30 or the unit mounting machine data 50.

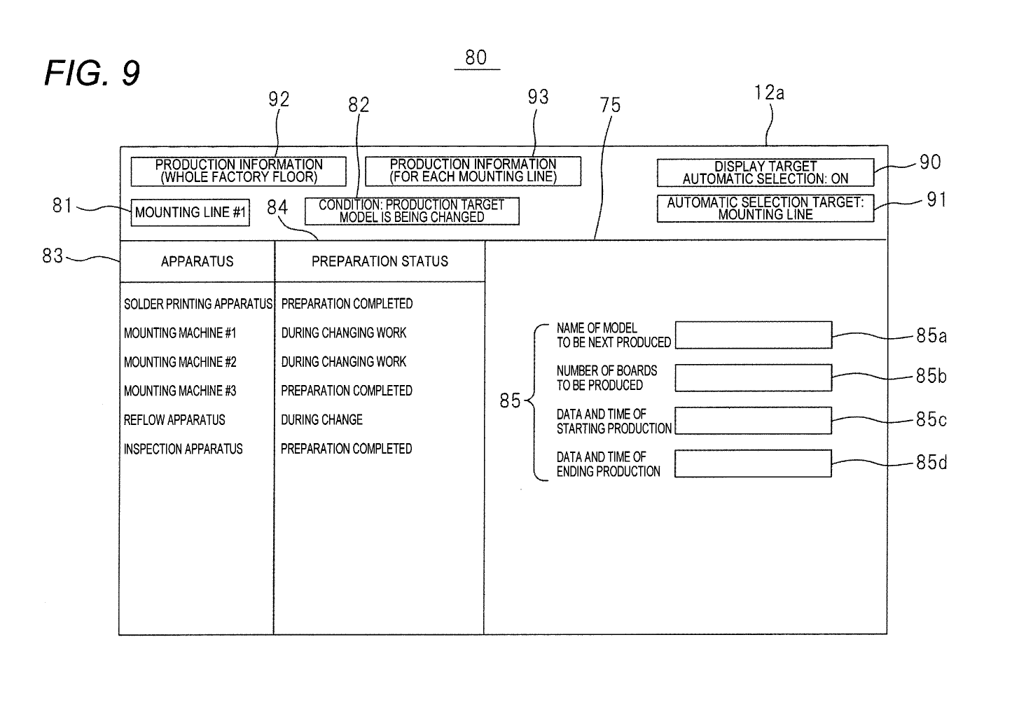

Next, the next-production data 80 will be described with reference to FIG. 9. The next-production data 80 indicate information relating to the next scheduled operation in the mounting line 2 or preparation for the next operation, and are displayed on the display screen 12a during the non-operating time of the mounting line 2. Specifically, the next-production data 80 includes various kinds of information of “Mounting line” 81, “Condition” 82, “Apparatus” 83, “Preparation status” 84, and “Information of model to be next produced” 85.

“Mounting line” 81 indicates information for specifying the mounting line 2 that is the display target. “Condition” 82 indicates the current condition of the mounting line 2. “Apparatus” 83 indicates the component mount apparatuses constituting the mounting line 2. “Preparation status” 84 indicates present preparation statuses of the component mount apparatuses for next-production.

The information of model to be next produced 85 indicates information relating to the model of a mounted board which is scheduled to be next produced, and includes various kinds of information of “Name of model to be next produced” 85a indicating the name of the model which is scheduled to be next produced, “Number of boards to be produced” 85b indicating the number of boards which are scheduled to be next produced, “Date and time of starting production” 85c indicating the date and time when production of the model which is scheduled to be next produced is to be started, and “Date and time of ending production” 85d indicating the date and time when production of the model which is scheduled to be next produced is to be ended.

Next, a display target automatic selection switch 90 and automatic-selection target selection switch 91 which are displayed together with the above-described data will be described. The display target automatic selection switch 90 determines validity/invalidity of switching of data based on the identification information transmitted from the mounting machines M3 to M5. In the case where the worker operates the display target automatic selection switch 90 to set “Display target automatic selection ON”, namely, the process section 14 switches the display screen 12a to the unit mounting machine data 50 of the mounting machine M3 to M5 corresponding to the identification information received by the second wireless communication section 11, or the unit mounting line data 30 of the mounting line 2 to which the mounting machine M3 to M5 belongs. In the case where “Display target automatic selection OFF” is set, by contrast, the process section 14 ignores the identification information transmitted from the mounting machines M3 to M5, and does not perform switching of the display screen 12a.

The automatic-selection target selection switch 91 is used for selecting data to be displayed on the display screen 12a in the case where the display target automatic selection switch 90 is set to “Display target automatic selection ON”. In the case where the worker operates the automatic-selection target selection switch 91 to set “Automatic selection: Mounting line”, the process section 14 causes the unit mounting line data 30 of the mounting line 2 corresponding to the identification information received by the second wireless communication section 11 under predetermined conditions, to be displayed. In the case where “Automatic selection: Mounting machine” is set, by contrast, the process section 14 causes the unit mounting machine data 50 of the mounting machine M3 to M5 corresponding to the identification information received by the second wireless communication section 11 under predetermined conditions, to be displayed.

Moreover, “Production information (whole factory floor) switch 92” is additionally displayed on each of the display screens 12a of the unit mounting line data 30 (FIG. 6), the unit mounting machine data 50 (FIG. 7), the component information data 70 (FIG. 8), and the next-production data 80 (FIG. 9). The production information (whole factory floor) switch 92 is used for switching the display screen 12a to the factory floor data 20. When the worker operates the switch 92, the process section 14 switches the display screen 12a to the factory floor data 20.

“Production information (for each mounting machine) switch 93” is additionally displayed on each of the display screens 12a of the unit mounting line data 30 (FIG. 6) and the next-production data 80 (FIG. 9). The production information (for each mounting machine) switch 93 is used for switching the display screen 12a to the unit mounting machine data 50. When the worker operates the switch 93, the process section 14 switches the display screen 12a to the unit mounting machine data 50.

“Production information (for each mounting line) switch 94” is additionally displayed on each of the display screen 12a of the unit mounting machine data 50 (FIG. 7) and the component information data 70 (FIG. 8). The production information (for each mounting line) switch 94 is used for switching the display screen 12a to the unit mounting line data 30. When the worker operates the switch 94, the process section 14 switches the display screen 12a to the unit mounting line data 30.

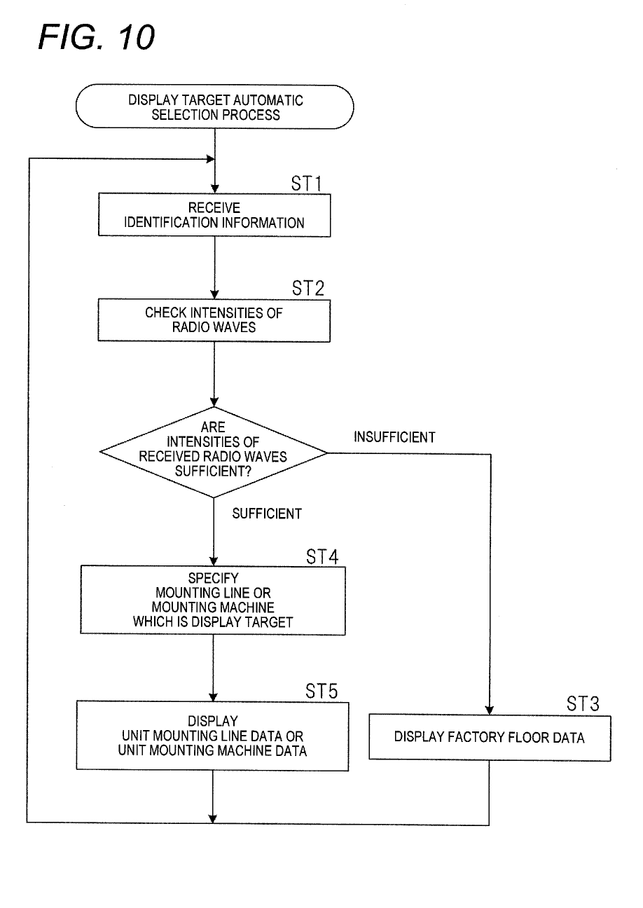

The electronic-component mounting system 1 of the embodiment is configured as described above. Next, the operation will be described with reference to FIG. 10. In the electronic-component mounting system 1 of the embodiment, an operation of a display target automatic selection process is executed in which, based on the identification information transmitted from the mounting machines M3 to M5, the process section 14 selects and displays data that are targets to be displayed on the display section 12 of the portable information terminal 6. The operation is executed under conditions that the automatic selection of the display target is valid, namely the display of the display target automatic selection switch 90 is set to “Display target automatic selection ON”. Hereinafter, the operation of the display target automatic selection process will be described under the assumption that the automatic selection of the display target is valid and the portable information terminal 6 is in a range where the terminal is communicable with the wireless communication station 5.

In the process section 14, first, the identification information which uses the radio waves transmitted from the mounting machines M3 to M5 of each of the mounting lines 2, as a medium is received by the second wireless communication section 11 (identification information receiving step in ST1). At this time, the second wireless communication section 11 can receive plural sets of identification information transmitted from the mounting machines M3 to M5 which are provided in the vicinity of the portable information terminal 6 (see FIG. 4).

Next, the process section 14 checks whether the intensity of the received radio wave (in the case of plural radio waves, the intensities of the radio waves) exceeds a predetermined reference value or not (radio wave intensity checking step of ST2). If the intensities of all the received radio waves are not larger than the predetermined reference value (the intensities of the radio waves are insufficient), the process section 14 causes the factory floor data 20 including the operation quality information to be displayed on the display screen 12a (factory floor data displaying step of ST3). This means that the portable information terminal 6 is located at a position which is separated from the mounting machines M3 to M5 by a given distance.

If, in the mounting machines M3 to M5, there is at least one machine which transmits a radio wave that exceeds the predetermined reference value (the intensity of the radio wave is sufficient), by contrast, the process section 14 specifies the mounting machine M3 to M5 or the mounting line 2 to which the mounting machine M3 to M5 belongs, as a display target (display target specifying step of ST4). Here, in the case where the display of the automatic-selection target selection switch 91 is “Automatic selection: Mounting machine”, the mounting machine M3 to M5 is specified, and, in the case where the display is “Automatic selection: Mounting line”, the mounting line 2 is specified. This means that the portable information terminal 6 is located in the vicinity of the mounting machines M3 to M5.

If there are a plurality of radio waves which exceed the predetermined reference value, the process section 14 specifies one of the mounting machines M3 to M5 that transmits a radio wave having the highest intensity, or the mounting line 2 to which the mounting machine M3 to M5 belongs. Namely, one of the mounting machines M3 to M5 that transmits a radio wave having the highest intensity (mounting line 2) is specified as the mounting machine M3 to M5 (mounting line 2) which is located nearest to the portable information terminal 6. That is, the portable information terminal 6 specifies the mounting machine M3 to M5 (mounting line 2) the operation quality information of which is to be displayed, based on the intensities of the radio waves including identification information. The above-described steps of (ST2) to (ST4) are executed by the display target selection section 16 of the process section 14.

Next, the display process section 17 of the process section 14 causes the unit mounting machine data 50 corresponding to the mounting machine M3 to M5 which is specified by the display target selection section 16, or the unit mounting line data 30 corresponding to the mounting line 2 to which the mounting machine M3 to M5 belongs, to be displayed on the display screen 12a (unit mounting machine data/unit mounting line data displaying step of ST5). These data include the above-described operation quality information. Thereafter, the process section 14 repeats the operations of (ST1) to (ST5) with a constant period.

In the case where the operation of the mounting line 2 (mounting machine M3 to M5) which is specified in (ST4) is stopped, the process section 14 causes the next-production data 80 of the mounting line 2 to be displayed on the display screen 12a. In the portable information terminal 6, in the case where the mounting line 2 (mounting machine M3 to M5) is being operated, the operation quality information is displayed on the display section 12, and, in the case where the mounting line is not operated, at least information relating to the next scheduled operation or preparation for the next operation is displayed on the display section 12.

As described above, the electronic-component mounting system 1 includes the function of, based on the identification information transmitted from the mounting lines 2 (mounting machines M3 to M5), displaying the operation quality information of the mounting line 2 (mounting machine M3 to M5) which is located in the vicinity of the portable information terminal 6, on the display section 12. The function is realized by: the information collection sections 3; the intranet 4; the wireless communication station 5, the communication networks 7; the first wireless communication section 10, second wireless communication section 11, display section 12, and process section 14 which are disposed in the portable information terminal 6; and the wireless communication sections 19 which are disposed in the mounting machines M3 to M5.

In the case where the worker wishes to manually switch the data displayed on the display screen 12a, the worker operates the display target automatic selection switch 90 to set “Display target automatic selection OFF”. As a result, the process section 14 of the portable information terminal 6 ignores the identification information transmitted from the mounting machines M3 to M5, and does not perform the operation of the display target automatic selection process. When, in this state, the worker operates an arbitrary display including the various switches 92 to 94 displayed on the display screen 12a, corresponding data can be displayed on the display screen 12a.

As described above, according to the electronic-component mounting system 1 of the embodiment, without moving to the information collection sections 3, the worker can check various kinds of operation quality information of the whole factory floor, the mounting lines 2, and the mounting machines M3 to M5, through the portable information terminal 6 in the range where wireless communication is enabled between the information collection sections 3 and the portable information terminal 6.

When the portable information terminal 6 is moved close to a desired one of the mounting lines 2 (mounting machines M3 to M5), the operation quality information (during the non-operating time, the next-production data 80) of the mounting line 2 or each of the mounting machines M3 to M5 belonging to the mounting line 2 can be automatically displayed on the display section 12 of the portable information terminal 6. In the case where the operation ratio of the mounting line 2 (mounting machine M3 to M5) is lowered, when information relating to a mounting failure included in the operation quality information, such as the failure rate and the number of failures, the analysis of the cause and measures for correction can be performed quickly and easily in the vicinity of the mounting line 2 (mounting machine M3 to M5).

In the vicinity of the mounting line 2 (mounting machine M3 to M5), moreover, the operation quality information corresponding to the mounting line can be checked. Therefore, it is possible to suppress a situation where the worker erroneously operates the terminal, and the operation quality information of another mounting line 2 (mounting machine M3 to M5) is displayed on the display section 12 of the portable information terminal 6.

In the embodiment, data communications are performed between the information collection sections 3 and the portable information terminal 6 through the wireless communication station 5 and the first wireless communication section 10. Alternatively, data communications between the information collection sections 3 and the portable information terminal 6 may be performed through the wireless communication sections 19 of the mounting machines M3 to M5 and the first wireless communication section 10 (or the second wireless communication section 11).

The method of specifying the mounting line 2 (mounting machine M3 to M5) which is located in the vicinity of the portable information terminal 6 is not limited to the one which is based on the intensity of the radio wave. For example, the specifying may be based on a method which uses the transmission direction of the radio wave received by the portable information terminal 6, the time difference between the transmission of the radio wave from the wireless communication section 19 and the reception of the radio wave by the portable information terminal 6, or the like.

Although the invention has been described in detail and with reference to the specific embodiment, it is obvious to a person skilled in the art that various modifications can be made without departing from the spirit and scope of the invention.

The application is based on Japanese Patent Application (No. 2012-271044) filed Dec. 12, 2012, and its disclosure is incorporated herein by reference.

### INDUSTRIAL APPLICABILITY

According to the invention, the worker can easily check the operation quality information through the portable information terminal, near the mounting line or the electronic-component mounting apparatus. The invention is useful in the field of electronic component mounting in which electronic components are mounted on a circuit board to produce a mounted board.

### DESCRIPTION OF REFERENCE SIGNS

1: Electronic-Component Mounting System

2: Mounting Line

3: Information Collection Section

4: Intranet

5: Wireless Communication Station

6: Portable Information Terminal

7: Communication Network

8: Main Section

10: First Wireless Communication Section

11: Second Wireless Communication Section

12: Display Section

14: Process Section

19: Wireless Communication Section

M3, M4, M5: Electronic-Component Mounting Apparatus (Mounting Machine)

1. An electronic-component mounting system comprising:
a plurality of mounting lines, each of which comprises an electronic-component mounting apparatus which performs a work of mounting an electronic component on a circuit board;
an operation information processor which collects operation information of the electronic-component mounting apparatus, applies a statistical process on the operation information, and produces operation quality information of the mounting lines; and
at least one portable information terminal which comprises a main section and a display section, and which is accessible to the operation information processor by wireless communication,
wherein an identification information transmission section which transmits identification information for identifying each of the mounting lines is disposed in each of the plurality of mounting lines, and a reception section which receives the identification information is disposed in the main section of the portable information terminal, and
wherein the portable information terminal displays on the display section the operation quality information of one of the mounting lines which is located near the portable information terminal based on the identification information transmitted from the mounting lines.

2. The electronic-component mounting system according to claim 1,
wherein when the mounting line is being operated, the portable information terminal displays the operation quality information on the display section, and
wherein when the mounting line is not operated, the portable information terminal displays at least information relating to a next scheduled operation or preparation for the next operation on the display section.

3. The electronic-component mounting system according to claim 1,
wherein based on an intensity of a radio wave including the identification information, the portable information terminal specifies the mounting line of which the operation quality information is to be displayed.

4. An electronic-component mounting system comprising:
a mounting line comprising a plurality of electronic-component mounting apparatuses, each of which performs a work of mounting an electronic component on a circuit board;
an operation information processor which collects operation information of the electronic-component mounting apparatuses, applies a statistical process on the operation information, and produces operation quality information of the electronic-component mounting apparatuses; and
at least one portable information terminal which comprises a main section and a display section, and which is accessible to the operation information processor by wireless communication,
wherein an identification information transmission section which transmits identification information for identifying each of the electronic-component mounting apparatus is disposed in each of the plurality of electronic-component mounting apparatuses, and a reception section which receives the identification information is disposed in the main section of the portable information terminal, and
wherein the portable information terminal displays on the display section the operation quality information of one of the electronic-component mounting apparatuses which is located near the portable information terminal based on the identification information transmitted from the electronic-component mounting apparatuses.

5. The electronic-component mounting system according to claim 4,
wherein when the electronic-component mounting apparatus is being operated, the portable information terminal displays the operation quality information is displayed on the display section, and
wherein when the electronic-component mounting apparatus is not operated, the portable information terminal displays at least information relating to a next scheduled operation or preparation for the next operation is displayed on the display section.

6. The electronic-component mounting system according to claim 4,
wherein based on an intensity of a radio wave including the identification information, the portable information terminal specifies the electronic-component mounting apparatus of which the operation quality information is to be displayed.
